(19) United States
(12) Patent Application Publication
(10) Pub. No.: US 2025/0374674 A1
(43) Pub. Date: Dec. 4, 2025

(54) COMPOSITE SUBSTRATE

(71) Applicant: NGK INSULATORS, LTD., Nagoya-shi (JP)

(72) Inventor: Takahiro YAMADERA, Nagoya-shi (JP)

(21) Appl. No.: 19/304,732

(22) Filed: Aug. 20, 2025

Related U.S. Application Data
(63) Continuation of application No. PCT/JP2024/010624, filed on Mar. 18, 2024.

(30) Foreign Application Priority Data
Mar. 28, 2023 (JP) 2023-050930

(51) Int. Cl. H10D 86/00; H10N 30/00

(52) U.S. Cl. CPC H10D 86/201; H10N 30/708

(57) ABSTRACT

A composite substrate includes: a functional substrate having a predetermined function; a support substrate configured to support the functional substrate; and an intermediate layer provided between the support substrate and the functional substrate. The functional substrate and the support substrate are joined to each other with the intermediate layer in between. Spaces are formed inside the intermediate layer at a predetermined area rate relative to an extending direction of the intermediate layer. The predetermined area rate is 1% or more and 7% or less.

### CROSS-REFERENCE TO RELATED APPLICATION

This application is a continuation application of PCT/JP2024/010624, filed on Mar. 18, 2024, which claims the benefit of priority of Japanese Patent Application No. JP2023-050930, filed on Mar. 28, 2023, the entire contents of which are incorporated herein by reference.

### 1. TECHNICAL FIELD

The present invention relates to a composite substrate.

### 2. DESCRIPTION OF RELATED ART

As a material of various devices such as a semiconductor device, a composite substrate configured by joining a plurality of substrates has been widely used. For example, as a composite substrate realizing a high-performance semiconductor device excellent in response speed and power consumption, an SOI (Silicon On Insulator) substrate configured by joining a support substrate and an Si substrate with an SiO₂ layer in between is known. Further, to realize a piezoelectric device such as an SAW (Surface Acoustic Wave) filter, a composite substrate using a piezoelectric material substrate made of LN (LiNbO₃), LT (LiTaO₃), or the like in place of the Si substrate is also known.

The composite substrate as described above can be fabricated by directly joining a functional substrate having a predetermined function like the Si substrate and the piezoelectric material substrate, and the support substrate with the SiO₂ layer functioning as an intermediate layer in between. In direct joining, surface activation treatment for activating joining surfaces is necessary.

As the surface activation treatment during fabrication of the composite substrate, Patent Literatures 1 (Japanese Patent Laid-Open No. 2016-225537) and 2 (International Publication No. WO 2022/190465) disclose a method using plasma by oxygen gas, nitrogen gas, argon gas, or other gas. The method can activate the joining surfaces at a relatively low temperature (about 400° C.).

The SiO₂ layer forming the intermediate layer is formed on each of the functional substrate and the support substrate, a joining surface on the functional substrate side and a joining surface on the support substrate side are directly joined after subjected to surface activation treatment. This makes it possible to form the composite substrate as described above. At this time, to improve joining strength, annealing treatment for heating the entire composite substrate to a predetermined temperature is performed after joining in some cases. By the annealing treatment, a covalent bond can be formed through an OH group on an interface between the joining surfaces (joining interface). This makes it possible to improve joining strength.

On the other hand, if moisture, gas, or the like used in steps before joining adheres to the joining surfaces, moisture, gas, or the like may be mixed as impurities into the SiO₂ layers after joining. When such impurities are heated together with the SiO₂ layers by the annealing treatment, voids (cavities) may occur on the joining interface due to expansion of the impurities. Occurrence of voids on the joining interface causes deterioration of joining strength, and when growth of the voids progresses, the functional substrate may be peeled off from the support substrate.

The present invention is made in consideration of the above-described circumstances, and a main object of the present invention is to realize a composite substrate in which occurrence of voids on a joining interference during annealing treatment can be suppressed.

### SUMMARY OF THE INVENTION

A composite substrate according to the present invention includes: a functional substrate having a predetermined function; a support substrate configured to support the functional substrate; and an intermediate layer provided between the support substrate and the functional substrate. The functional substrate and the support substrate are joined to each other with the intermediate layer in between. Spaces are formed inside the intermediate layer at a predetermined area rate relative to an extending direction of the intermediate layer. The predetermined area rate is 1% or more and 7% or less.

According to the present invention, it is possible to realize the composite substrate in which occurrence of voids on the joining interface during the annealing treatment can be suppressed.

### BRIEF DESCRIPTION OF THE DRAWINGS

FIG. 1 is a schematic cross-sectional view illustrating an outline configuration of a composite substrate according to an embodiment of the present invention.

FIGS. 2A, 2B and 2C are diagrams illustrating examples of steps of manufacturing the composite substrate according to the embodiment of the present invention.

FIGS. 3D, 3E, 3F and 3G are diagrams illustrating examples of the steps of manufacturing the composite substrate according to the embodiment of the present invention.

FIGS. 4H and 4I are diagrams illustrating examples of the steps of manufacturing the composite substrate according to the embodiment of the present invention.

FIGS. 5J, 5K, 5L and 5M are diagrams illustrating examples of the steps of manufacturing the composite substrate according to the embodiment of the present invention.

FIGS. 6A and 6B are diagrams illustrating an AFM image and an enhanced image on a joining interface according to Example 1.

FIGS. 7A and 7B are diagrams illustrating an AFM image and an enhanced image on a joining interface according to Example 2.

FIGS. 8A and 8B are diagrams illustrating an AFM image and an enhanced image on a joining interface according to Comparative Example 2.

FIGS. 9A and 9B are diagrams illustrating an AFM image and an enhanced image on a joining interface according to Comparative Example 4.

FIG. 10 is a graph summarizing the relationship between an area rate of spaces and the number of voids on the joining interface.

### DESCRIPTION OF PREFERRED EMBODIMENTS

An embodiment of the present invention is described below with reference to drawings; however, the present invention is not limited to the embodiment. To further clarify the description, a width, a thickness, a shape, and the like of each portion may be schematically illustrated in the drawings as compared with the embodiment; however, the drawings are merely illustrative, and do not limit interpretation of the present invention.

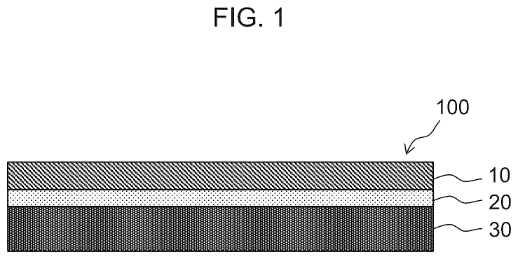

FIG. 1 is a schematic cross-sectional view illustrating an outline configuration of a composite substrate according to the embodiment of the present invention. A composite substrate 100 according to the present embodiment has a structure in which a functional substrate 10 having a predetermined function is joined to a support substrate 30 with an intermediate layer 20 in between.

The functional substrate 10 has a function for realizing various devices, and is made of a material corresponding to the function. For example, in the composite substrate 100 used for a SAW filter or an optical waveguide, a piezoelectric material substrate may be configured, and examples of a material include a piezoelectric material such as LN (LiNbO₃: lithium niobate) and LT (LiTaO₃: lithium tantalate). In the composite substrate 100 used as an SOI substrate, the functional substrate 10 is configured by an Si substrate as a semiconductor. Other than above, various materials corresponding to applications of the composite substrate 100 can be used for the functional substrate 10.

In the following, an example in a case where the functional substrate 10 is made of an LT material is described; however, this is true of a case of using the other material.

The intermediate layer 20 is provided on the support substrate 30, and is disposed between the functional substrate 10 and the support substrate 30. A material of the intermediate layer 20 is, for example, SiO₂.

The intermediate layer 20 may be formed by an optional appropriate method. For example, the intermediate layer 20 may be formed by physical vapor deposition such as sputtering, vacuum vapor deposition, and ion assisted deposition (IAD), chemical vapor deposition, or atomic layer deposition (ALD). The intermediate layer 20 can be formed at, for example, a room temperature (25° C.) to 300° C.

The support substrate 30 supports the functional substrate 10. As the support substrate 30, an optional appropriate substrate may be used. The support substrate 30 may be made of a single-crystalline substance or a polycrystalline substance. Alternatively, the support substrate 30 may be made of a metal. The functional substrate 10 and the support substrate 30 are joined to each other with the intermediate layer 20 in between.

A material configuring the support substrate 30 is preferably selected from a group consisting of silicon, sialon, sapphire, cordierite, mullite, glass, quartz, crystal, alumina, SUS, an iron-nickel alloy (42 alloy), MgF₂, CaF₂, and brass. An optional appropriate thickness may be adopted for the support substrate 30.

The silicon may be single-crystalline silicon, polycrystalline silicon, or high-resistance silicon.

Typically, the sialon is a ceramic obtained by sintering a mixture of silicon nitride and alumina, and has a composition represented by, for example, Si₆-wAlwOwN₈-w. More specifically, the sialon has a composition in which alumina is mixed into silicon nitride. In the formula, w represents a mixing rate of alumina, and is preferably 0.5 or more and 4.0 or less.

Typically, the sapphire is a single-crystalline substance having a composition of Al₂O₃, and the alumina is a polycrystalline substance having a composition of Al₂O₃. The alumina is preferably translucent alumina.

Typically, the cordierite is a ceramic having a composition of 2MgO·2Al₂O₃·5SiO₂, and the mullite is a ceramic having a composition in a range from 3Al₂O₃·2SiO₂ to 2Al₂O₃·SiO₂.

Although not illustrated, the composite substrate 100 may further include an optional layer. Types, functions, number, combination, arrangement, and the like of such layers may be appropriately set depending on purposes.

The composite substrate 100 may be manufactured in an optional appropriate shape. In one embodiment, the composite substrate 100 may be manufactured in a form of a so-called wafer. A size of the composite substrate 100 may be appropriately set depending on purposes, for example, a diameter of a wafer (substrate) may be set to 50 mm to 200 mm.

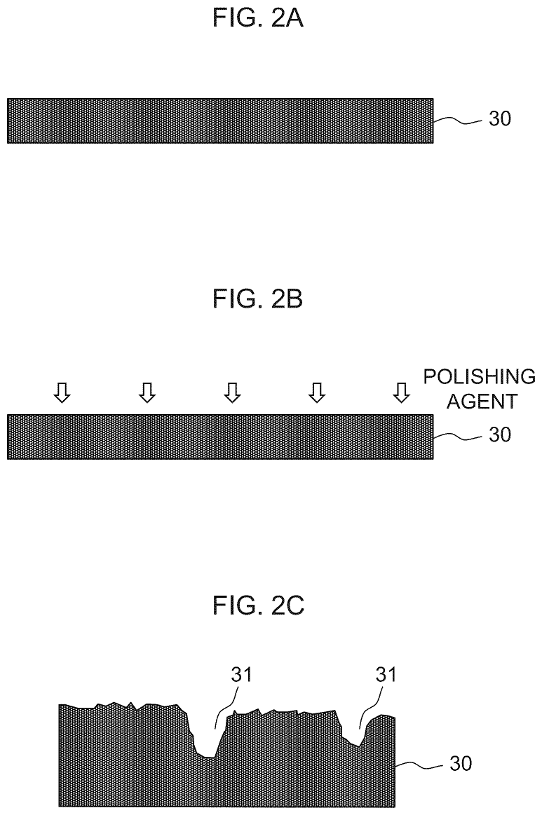

FIGS. 2A to 5M are diagrams illustrating examples of steps of manufacturing the composite substrate according to the embodiment of the present invention.

FIG. 2A illustrates a preparation step among the steps of manufacturing the composite substrate 100. In this step, the support substrate 30 is prepared. For example, a high-resistance Si substrate (having resistivity of 2 kΩ·cm or more) having a thickness of 0.23 mm is used as the support substrate 30.

FIG. 2B illustrates a blast processing step among the steps of manufacturing the composite substrate 100. In this step, blast processing is performed on the support substrate 30 prepared in the preparation step illustrated in FIG. 2A by injecting, for example, a polishing agent having an average particle diameter of about 2 μm to a surface of the support substrate 30 from a blast gun. As the polishing agent, powder of, for example, SiC, glass, or alumina is preferably used.

When a distance between the support substrate 30 and the blast gun in the blast processing is excessively short (for example, less than 10 mm), the polishing agent previously injected from the blast gun rebounds on the surface of the support substrate 30, and collides with the polishing agent subsequently injected. Therefore, the polishing agent subsequently injected does not reach the support substrate 30, and the blast processing hardly progresses. In contrast, when the distance is excessively long (for example, 100 mm or more), a speed when the polishing agent injected from the blast gun reaches the surface of the support substrate 30 is excessively low, and accordingly, motion energy necessary for the blast processing cannot be obtained. Therefore, the distance between the support substrate 30 and the blast gun in the blast processing is preferably within a range from about 10 mm to about 100 mm.

FIG. 2C illustrates a state where a part of a cross-section of the support substrate 30 after the blast processing is enlarged. In the blast processing step illustrated in FIG. 2B, the surface of the support substrate 30 is non-uniformly shaved by the polishing agent, and is processed in an uneven shape as illustrated in FIG. 2C. On the surface of the support substrate 30 having the uneven shape, holes 31 are partially formed by being dug deeper than the other portions.

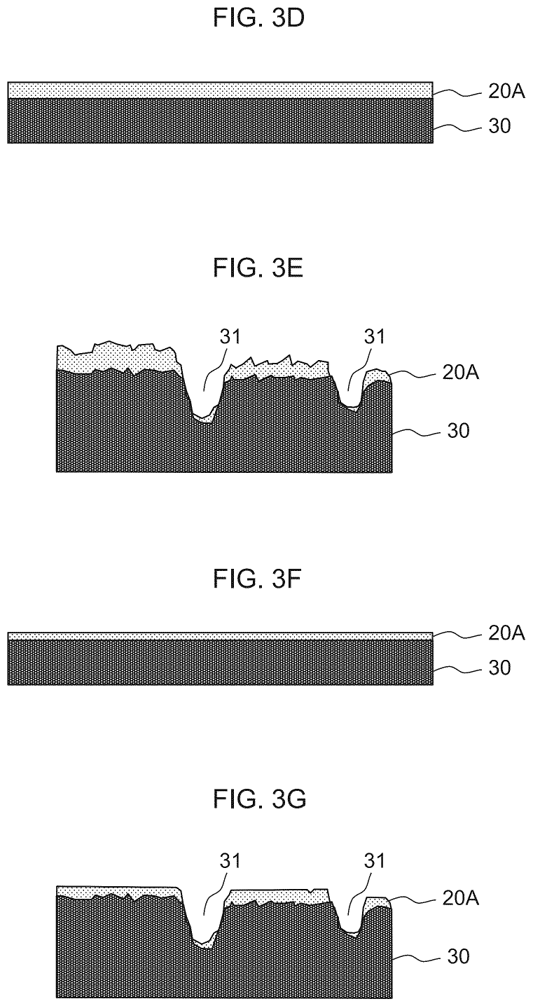

FIG. 3D illustrates a film formation step on the support substrate 30 among the steps of manufacturing the composite substrate 100. In this step, an amorphous body of SiO₂ is formed to have, for example, a predetermined thickness on the surface of the support substrate 30 processed in the uneven shape in the blast processing step illustrated in FIG. 2B. As a result, a first intermediate film 20A for configuring the intermediate layer 20 is formed.

FIG. 3E illustrates a state where a part of the cross-section of the support substrate 30 after film formation is enlarged. In the film formation step illustrated in FIG. 3D, the first intermediate film 20A is formed along the surface of the support substrate 30 processed in the uneven shape.

FIG. 3F illustrates a joining surface planarization step among the steps of manufacturing the composite substrate 100. In this step, a joining surface of the support substrate 30 (first intermediate film 20A) is planarized by polishing a surface of the first intermediate film 20A formed on the support substrate 30 in the film formation step illustrated in FIG. 3D.

FIG. 3G illustrates a state where a part of the cross-section of the support substrate 30 after planarization is enlarged. In the planarization step illustrated in FIG. 3F, the surface of the first intermediate film 20A is polished, and unevenness formed along the surface of the support substrate 30 is entirely planarized. However, the holes 31 partially formed deep are not wholly planarized, and remain.

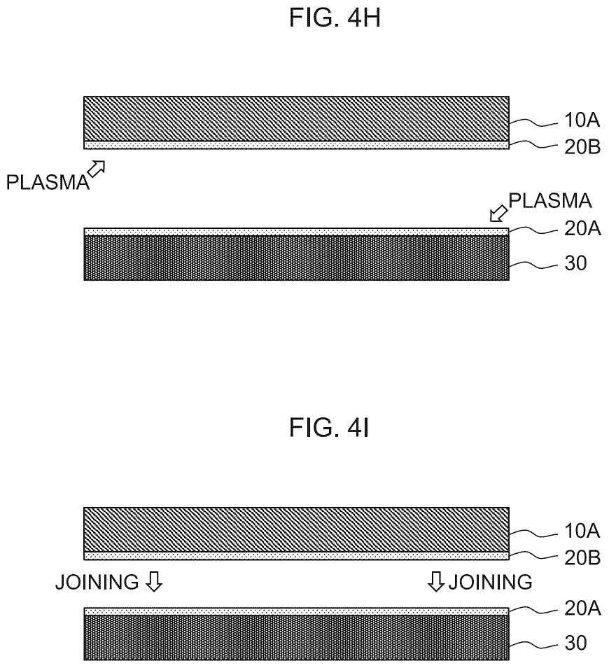

FIG. 4H illustrates an activation step among the steps of manufacturing the composite substrate 100. In this step, an LT substrate 10A that is made of an LT material having a predetermined thickness and has a surface polished to a mirror finish is first prepared. A film formation step and a planarization step similar to the steps illustrated in FIGS. 3D and 3F are performed to form a second intermediate film 20B on the LT substrate 10A and to planarize a surface of the second intermediate film 20B. Next, activation processing is performed by applying N₂ plasma to the surface of the first intermediate film 20A on the support substrate 30 planarized in the planarization step illustrated in FIG. 3F and the surface of the second intermediate film 20B on the LT substrate 10A, thereby activating the surfaces.

FIG. 4I illustrates a joining step among the steps of manufacturing the composite substrate 100. In this step, the surface of the first intermediate film 20A on the support substrate 30 side and the surface of the second intermediate film 20B on the LT substrate 10A side both activated in the activation step illustrated in FIG. 4H are directly joined to each other, to form a joined body of the support substrate 30 and the LT substrate 10A with these surfaces as joining surfaces.

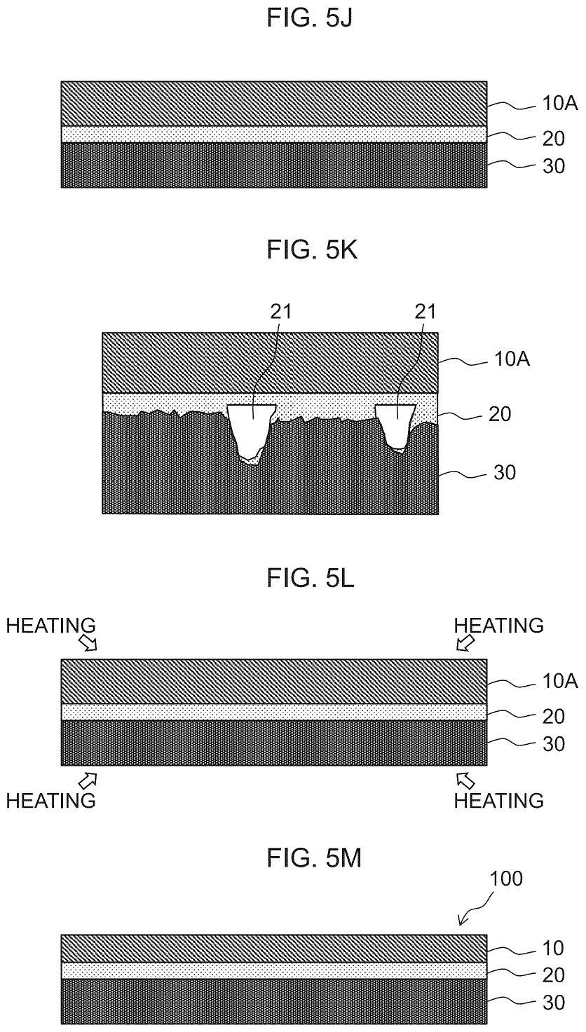

FIG. 5J illustrates the joined body of the support substrate 30 and the LT substrate 10A. In the joining step illustrated in FIG. 4I, the first intermediate film 20A and the second intermediate film 20B are joined and integrated to form the intermediate layer 20. As a result, the support substrate 30 and the LT substrate 10A are joined to each other with the intermediate layer 20 in between, and the joined body of the support substrate 30 and the LT substrate 10A as illustrated in FIG. 5J is formed.

FIG. 5K illustrates a state where a part of a cross-section of the joined body illustrated in FIG. 5J is enlarged. In the joining step illustrated in FIG. 4I, openings of the holes 31 partially formed in the first intermediate film 20A are closed by the second intermediate film 20B. As a result, inside the intermediate layer 20 in which the first intermediate film 20A and the second intermediate film 20B are integrated, spaces 21 are partially formed at a predetermined area rate relative to an extending direction of the intermediate layer 20. The predetermined area rate is 1% or more and 7% or less. When the area rate is less than 1%, voids largely occur, whereas when the area rate is greater than 7%, joining intensity is insufficient, and the functional substrate is easily peeled off in thinning processing. The area rate is more preferably 1.4% or more and 6.6% or less.

FIG. 5L illustrates an annealing treatment step among the steps of manufacturing the composite substrate 100. In this step, the joined body of the support substrate 30 and the LT substrate 10A formed in the joining step illustrated in FIG. 4I is heated to a predetermined temperature. This forms a covalent bond through an OH group inside the intermediate layer 20, and improves joining strength of the joined body.

In the annealing treatment step illustrated in FIG. 5L, impurities such as moisture and gas that adhere to the surfaces of the first intermediate film 20A and the second intermediate film 20B in the planarization step and the activation step described above and are confined inside the intermediate layer 20 in the subsequent joining step may be expanded by heating. Such expansion of impurities causes occurrence of voids on the joining interface of the first intermediate film 20A and the second intermediate film 20B inside the intermediate layer 20, and leads to deterioration of joining strength. When growth of the voids further progresses, the LT substrate 10A may be peeled off from the support substrate 30.

In the present embodiment, the spaces 21 are partially formed inside the intermediate layer 20 as described above. Therefore, even in the case where impurities such as moisture and gas confined inside the intermediate layer 20 are expanded by heating, the impurities are likely to stay inside the spaces 21. This suppresses occurrence of voids on the joining interface inside the intermediate layer 20 during the annealing treatment, and suppresses deterioration of joining strength and peeling of the LT substrate 10A.

FIG. 5M illustrates a thinning processing step among the steps of manufacturing the composite substrate 100. In this step, the LT substrate 10A of the joined body after the annealing treatment step illustrated in FIG. 5L is polished and thinned to a predetermined thickness, which results in formation of the functional substrate 10 made of the LT material. The LT substrate 10A can be polished and thinned by using, for example, cutting processing, CMP (Chemical Mechanical Polish) processing, or surface planarization processing using a gas cluster ion beam.

By the above-described steps, the composite substrate 100 having the structure illustrated in FIG. 1 is manufactured.

### EXAMPLES

Examples for verifying the structure of the composite substrate according to the present invention are specifically described. The following procedure was performed at a room temperature unless otherwise noted.

### Example 1

A joined body was fabricated by the manufacturing steps described with reference to FIGS. 2A to 5M. More specifically, the LT substrate 10A having a thickness of 0.25 mm and the support substrate 30 made of a high-resistance Si substrate having a thickness of 0.23 mm were used. A blast gun was installed at a position separated by 40 mm from the surface of the support substrate 30, and blast processing was performed by injecting a powdered polishing agent having an average particle diameter of 2 μm at pressure of 0.25 MPa for four minutes. Thereafter, an amorphous body of SiO₂ having a thickness of 0.5 μm was formed on each of the surface of the support substrate 30 after the blast processing and the surface of the LT substrate 10A to form the first intermediate film 20A and the second intermediate film 20B. The surfaces of the first intermediate film 20A and the second intermediate film 20B were planarized by being polished by about 0.1 μm by CMP.

Next, N₂ plasma was applied to activate the surface of the first intermediate film 20A on the support substrate 30 and the surface of the second intermediate film 20B on the LT substrate 10A, and these surfaces were then superimposed on each other and were directly joined by being pressurized under an ambient temperature environment. As a result, the first intermediate film 20A and the second intermediate film 20B were integrated to form the intermediate layer 20, and the joined body in which the support substrate 30 and the LT substrate 10A were joined to each other with the intermediate layer 20 in between was obtained.

Thereafter, the obtained joined boy was placed in a high-temperature furnace, and annealing treatment was performed by increasing a temperature from a room temperature to 130° C., maintaining the temperature for about four hours, and then returning the temperature to the room temperature.

Thereafter, the LT substrate 10A of the joined body after the annealing treatment was ground and polished to thin the LT substrate 10A to 1 μm, thereby forming the functional substrate 10. As a result, the composite substrate 100 having the structure illustrated in FIG. 1 was obtained. In the composite substrate 100 according to Example 1, occurrence of voids on the joining interface inside the intermediate layer 20 was not observed.

### Example 2

In the blast processing step among the manufacturing steps according to Example 1, the average particle diameter of the used polishing agent was changed to 3 μm, and the other conditions were set to the same conditions as in Example 1. The conditions in the other steps were set to the same conditions as in Example 1. Under such conditions, the composite substrate 100 having the structure illustrated in FIG. 1 was obtained. Even in the composite substrate 100 according to Example 2, occurrence of voids on the joining interface inside the intermediate layer 20 was not observed.

### Comparative Example 1

Among the manufacturing steps according to Example 1, the blast processing step was omitted, and the conditions in the other steps were set to the same conditions as in Example 1. Under such conditions, the composite substrate 100 having the structure illustrated in FIG. 1 was obtained. In the composite substrate 100 according to Comparative Example 1, about 80 voids occurred on the joining interface inside the intermediate layer 20.

### Comparative Example 2

In the blast processing step among the manufacturing steps according to Example 1, the average particle diameter of the used polishing agent was changed to 1.2 μm, and the other conditions were set to the same conditions as in Example 1. The conditions in the other steps were set to the same conditions as in Example 1. Under such conditions, the composite substrate 100 having the structure illustrated in FIG. 1 was obtained. In the composite substrate 100 according to Comparative Example 2, about 20 voids occurred on the joining interface inside the intermediate layer 20.

### Comparative Example 3

In the blast processing step among the manufacturing steps according to Example 1, the average particle diameter of the used polishing agent was changed to greater than 3 μm, and the other conditions were set to the same conditions as in Example 1. The conditions in the other steps were set to the same conditions as in Example 1. In Comparative Example 3, joining strength of the joined body after annealing treatment was insufficient, and the LT substrate 10A was peeled off in the subsequent thinning processing step. Therefore, the composite substrate 100 having the structure illustrated in FIG. 1 was not obtained.

### Comparative Example 4

In the blast processing step among the manufacturing steps according to Example 1, the installation position of the blast gun was changed to a position separated by 100 mm from the surface of the support substrate 30, and the other conditions were set to the same conditions as in Example 1. The conditions in the other steps were set to the same conditions as in Example 1. Under such conditions, the composite substrate 100 having the structure illustrated in FIG. 1 was obtained.

### (Check of Joining Interface)

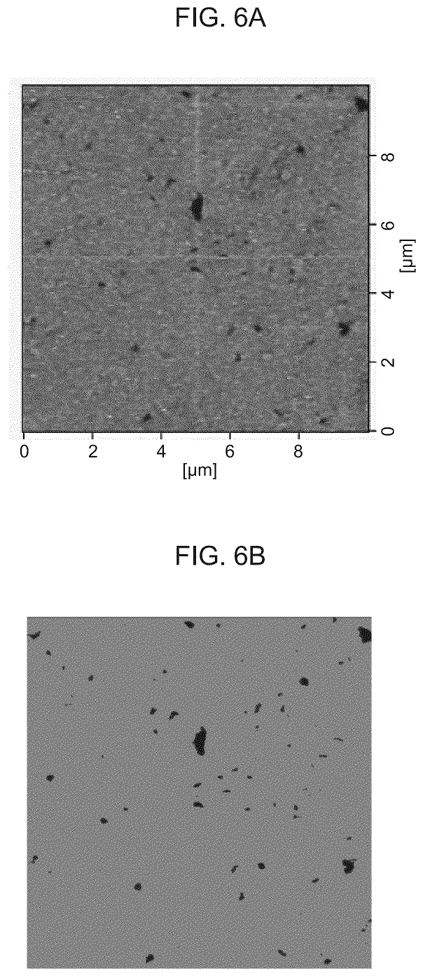

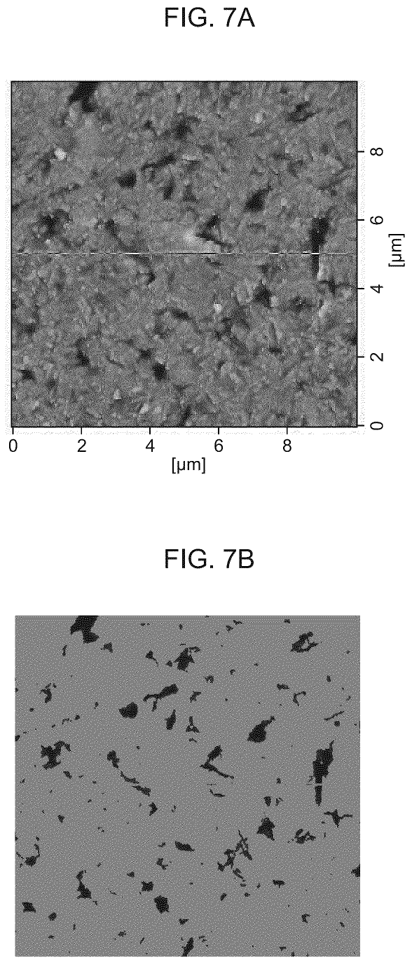

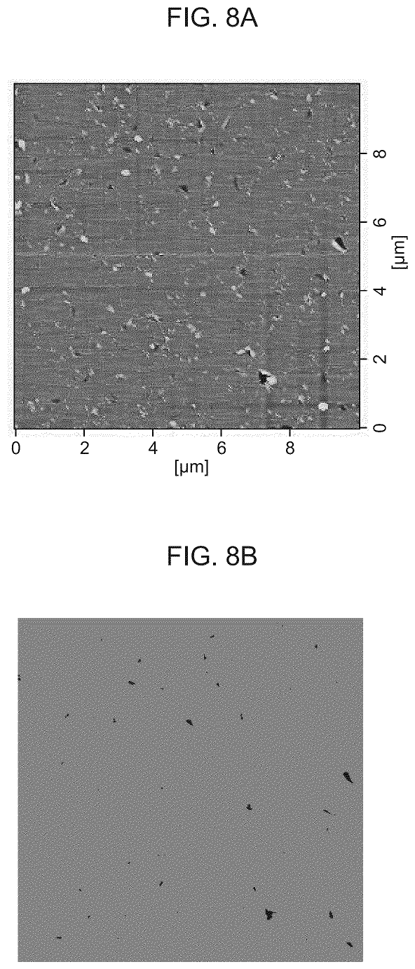

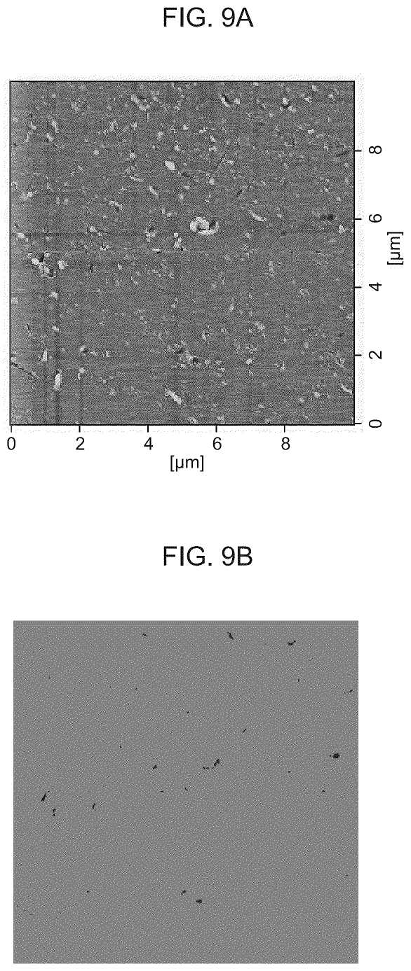

To check the joining interface inside the intermediate layer 20 in each of the composite substrates 100 fabricated in Examples 1 and 2 and Comparative Examples 2 and 4 described above, the functional substrate 10 made of the LT substrate 10A having a thickness of 1 μm was removed by polishing, and further, a portion (portion corresponding to thickness of 0.5 μm) of the intermediate layer 20 corresponding to the second intermediate film 20B before joining was removed by polishing. Thereafter, an exposed surface (joining interface) of each of the composite substrates 100 after polishing was observed by an AFM (Atomic Force Microscope) to acquire an AFM image. Further, predetermined image processing was performed on each of the acquired AFM images to acquire an enhanced image in which spaces on the joining interface were enhanced. FIGS. 6A and 6B respectively illustrate an AFM image and an enhanced image on the joining interface according to Example 1. FIGS. 7A and 7B respectively illustrate an AFM image and an enhanced image on the joining interface according to Example 2. FIGS. 8A and 8B respectively illustrate an AFM image and an enhanced image on the joining interface according to Comparative Example 2. FIGS. 9A and 9B respectively illustrate an AFM image and an enhanced image on the joining interface according to Comparative Example 4.

From the enhanced image according to Example 1 illustrated in FIG. 6B, an area rate of the spaces relative to the extending direction of the intermediate layer 20 was calculated. The area rate was 1.4%. From the enhanced image according to Example 2 illustrated in FIG. 7B, an area rate of the spaces relative to the extending direction of the intermediate layer 20 was calculated. The area rate was 6.68. From the enhanced image according to Comparative Example 2 illustrated in FIG. 8B, an area rate of the spaces relative to the extending direction of the intermediate layer 20 was calculated. The area rate was 0.38. From the enhanced image according to Comparative Example 4 illustrated in FIG. 9B, an area rate of the spaces relative to the extending direction of the intermediate layer 20 was calculated. The area rate was 0.19%.

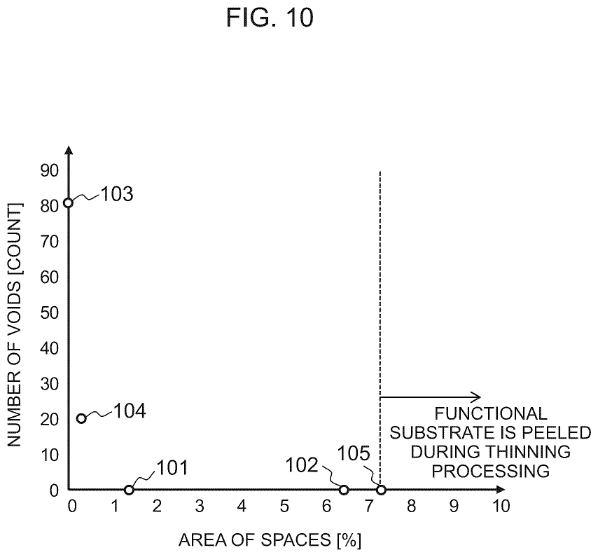

FIG. 10 is a graph summarizing the relationship between the area rate of the spaces and the number of voids on the joining interface in each of the composite substrates 100 according to Examples 1 and 2 and Comparative Examples 1 to 3. In FIG. 10, a point 101 indicates Example 1, a point 102 indicates Example 2, a point 103 indicates Comparative Example 1, a point 104 indicates Comparative Example 2, and a point 105 indicates Comparative Example 3. In Comparative Example 1, since the blast processing step was omitted as described above, the area rate of the spaces was regarded as 0%. Further, in Comparative Example 3, since the average particle diameter of the polishing agent was greater than the average particle diameter of the polishing agent according to Example 2 (average particle diameter of 3 μm), the area rate of the spaces was 7.5% that was greater than the value (6.6%) calculated in Example 2.

It is found from the graph illustrated in FIG. 10 that, when the area rate of the spaces is within a range from 1% to 7%, sufficient joining strength can be obtained while occurrence of voids on the joining interface inside the intermediate layer 20 is suppressed to zero. In other words, in the composite substrate 100 fabricated by the steps illustrated in FIGS. 2A to 5M, the condition in the above-described blast processing step is set such that the spaces are formed inside the intermediate layer 20 at the area rate within the range from 1% to 78 relative to the extending direction of the intermediate layer 20. This makes it possible to realize the composite substrate 100 in which occurrence of voids on the joining interface during the annealing treatment can be suppressed.

The embodiment according to the present invention described above achieves the following functional effects.

(1) A composite substrate 100 includes: a functional substrate 10 having a predetermined function; a support substrate 30 configured to support the functional substrate 10; and an intermediate layer 20 provided between the support substrate 30 and the functional substrate 10. The functional substrate 10 and the support substrate 30 are joined to each other with the intermediate layer 20 in between. Spaces are formed inside the intermediate layer 20 at a predetermined area rate relative to an extending direction of the intermediate layer 20. The predetermined area rate is 1% or more and 7% or less. Accordingly, it is possible to realize the composite substrate 100 in which occurrence of voids on a joining interface during annealing treatment can be suppressed.

(2) The intermediate layer 20 is preferably made of SiO₂. This makes it possible to firmly join the functional substrate 10 and the support substrate 30 with the intermediate layer 20 in between.

(3) The functional substrate 10 may be a piezoelectric material substrate made of an LN (LiNbO₃) material or an LT (LiTaO₃) material. Further, the functional substrate 10 may be a semiconductor substrate made of an Si material. This makes it possible to use a substrate having various functions as the functional substrate 10 based on an application of the composite substrate 100.

The present invention is not limited to the above-described embodiment, and can be implemented using optional components without departing from the spirit of the present invention.

The embodiment and modification described above are merely illustrative, and the present invention is not limited to the contents of the embodiment and modification unless the features of the invention are impaired. Although various embodiments and modifications are described above, the present invention is not limited to the contents of the embodiments and modifications. The other forms considered within the scope of the technical idea of the present invention are also included in the scope of the present invention.

What is claimed is:

1. A composite substrate, comprising:
a functional substrate having a predetermined function;
a support substrate configured to support the functional substrate; and
an intermediate layer provided between the support substrate and the functional substrate, wherein
the functional substrate and the support substrate are joined to each other with the intermediate layer in between,
spaces are formed inside the intermediate layer at a predetermined area rate relative to an extending direction of the intermediate layer, and
the predetermined area rate is 18 or more and 7% or less.

2. The composite substrate according to claim 1, wherein the intermediate layer is made of SiO₂.

3. The composite substrate according to claim 1, wherein the functional substrate is a piezoelectric material substrate.

4. The composite substrate according to claim 1, wherein the functional substrate is a semiconductor substrate made of an Si material.
